(19) United States
(12) Patent Application Publication
(10) Pub. No.: US 2015/0380369 A1
(43) Pub. Date: Dec. 31, 2015

(54) WAFER PACKAGING STRUCTURE AND PACKAGING METHOD

(71) Applicant: NANTONG FUJITSU MICROELECTRONICS CO., LTD, Nantong, Jiangsu (CN)

(72) Inventor: Wanchun DING, Nantong (CN)

(21) Appl. No.: 14/764,151

(22) PCT Filed: Sep. 26, 2014
(86) PCT No.: PCT/CN2014/087488

§ 371 Date: Jul. 28, 2015

(30) Foreign Application Priority Data
Sep. 30, 2013 (CN) 201310462970.9
Sep. 30, 2013 (CN) 201310462982.1

(51) Int. Cl. H01L 23/00; H01L 25/065; H01L 23/29; H01L 25/00; H01L 23/31; H01L 23/544

(52) U.S. Cl. CPC H01L 24/09; H01L 23/3178; H01L 24/03; H01L 23/544; H01L 23/293; H01L 24/80; H01L 25/50; H01L 25/0655; H01L 2223/54426; H01L 2224/32225; H01L 2224/12105; H01L 2924/15153; H01L 2224/24137; H01L 2924/157; H01L 2224/92244; H01L 2224/0311; H01L 2224/04026; H01L 2224/04042

(57) ABSTRACT

The present invention provides a wafer packaging structure and a wafer packaging method. The wafer packaging structure includes: a substrate, wherein grooves are formed in one surface of the substrate, and chips are arranged in the grooves; a material sealing layer formed on the substrate, wherein connecting components of the chips are exposed from the surface of the material sealing layer; a wiring layer formed on the material sealing layer and electrically connected with the connecting components; a protective film layer formed on the wiring layer, wherein the protective film layer is provided with openings for exposing the wiring layer; lower ball metal layers formed in the openings and connected with the wiring layer; and metal balls formed on the lower ball metal layers. The wafer packaging structure provided by the present invention can be used for packaging a plurality of chips, thereby having a higher integration level and a higher integration degree.

### FIELD OF THE INVENTION

The present invention relates to the technical field of semiconductors, and particularly relates to a wafer packaging structure and a wafer packaging method.

### BACKGROUND OF THE INVENTION

With the continuous development of integrated circuit technology, development of electronic products increasingly moves towards the direction of miniaturization, intelligence and high reliability, integrated circuit package directly affects the performances of integrated circuits, electronic modules and even the entire machine, and under the condition of gradually decreasing sizes and continuously increasing integration levels of integrated circuit wafers, higher and higher requirements are proposed for integrated circuit package termination in the electronic industry. With the light, thin, short and small trends of semiconductor products and the continuously increased requirements on system functions of the products, how to further improve the integration level of system-in-package becomes a problem to be urgently solved by those skilled in the art.

### SUMMARY OF THE INVENTION

The technical problem to be solved in the present invention is how to further improve the integration level of system-in-package.

To solve the above technical problem, the present invention provides a wafer packaging structure, including:

a substrate, wherein grooves are formed in one surface of the substrate, and chips are arranged in the groove;

a material sealing layer formed on the substrate, wherein connecting components of the chips are exposed from the surface of the material sealing layer;

a wiring layer formed on the material sealing layer and electrically connected with the connecting components;

a protective film layer formed on the wiring layer, wherein the protective film layer is provided with openings for exposing the wiring layer;

lower ball metal layers formed in the openings and connected with the wiring layer; and

metal balls formed on the lower ball metal layers.

The present invention provides a wafer packaging method, including: providing a substrate, forming grooves in one surface of the substrate, and adhering chips in the groove;

forming a material sealing layer on the substrate, and exposing connecting components of the chips;

forming a wiring layer electrically connected with the connecting components on the material sealing layer;

forming a protective film layer on the wiring layer, and forming openings for exposing the wiring layer; and

forming lower ball metal layers connected with the wiring layer in the openings, and

forming metal balls on the lower ball metal layers. The wafer packaging structure provided by the present invention can be used for packaging a plurality of different chips, thereby having a higher integration level and a higher integration degree.

### BRIEF DESCRIPTION OF THE DRAWINGS

To illustrate technical solutions in the embodiments of the present invention or in the prior art more clearly, the accompanying drawings which are needed in the description of the embodiments or the prior art are briefly introduced below. Apparently, the accompanying drawings in the description below are merely some of the embodiments of the present invention, based on which other accompanying drawings may be obtained by those of ordinary skill in the art without any creative effort.

FIG. 1 is a structural schematic diagram of an embodiment of a wafer packaging structure provided by the present invention.

FIG. 2 is a flowchart of an embodiment of a wafer packaging method provided by the present invention.

FIG. 3a to FIG. 3f are structural schematic diagrams of a packaging structure in steps of an embodiment of the wafer packaging method provided by the present invention.

### DETAILED DESCRIPTION OF THE EMBODIMENTS

In order to make the purposes, technical solutions and advantages of the embodiments of the present invention clearer, the technical solutions in the embodiments of the present invention will be clearly and completely described below in combination with accompanying drawings. Apparently, the embodiments described below are merely a part, but not all, of the embodiments of the present invention. Elements and features described in one accompanying drawing or one embodiment of the present invention can be combined with elements and features shown in one or more other accompanying drawings or embodiments. It should be noted that, for the purpose of clarity, expressions and descriptions of components and processing irrespective to the present invention and known to those of ordinary skill in the art are omitted in the accompanying drawings and the illustration. All of other embodiments, obtained by those of ordinary skill in the art based on the embodiments of the present invention without any creative effort, fall into the protection scope of the present invention.

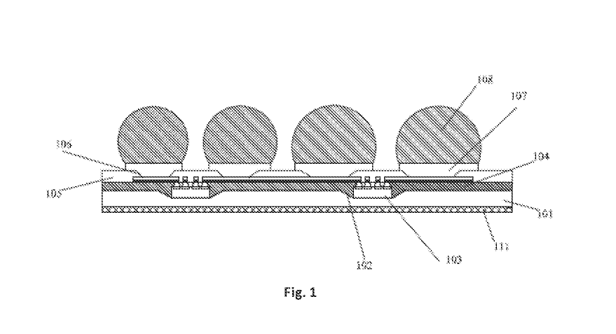

See FIG. 1, the embodiment provides a wafer packaging structure, including:

a substrate 101, wherein grooves 102 are formed in one surface of the substrate 101, and chips 103 are arranged in the grooves 102;

a material sealing layer 104 formed on the substrate 101, wherein connecting components of the chips 103 are exposed from the surface of the material sealing layer 104;

a wiring layer formed on the material sealing layer 104 and electrically connected with the connecting components;

a protective film layer 105 formed on the wiring layer, wherein the protective film layer 105 is provided with openings 106 for exposing the wiring layer; lower ball metal layers 107 formed in the openings 106 and connected with the wiring layer; and

metal balls 108 formed on the lower ball metal layers 107.

The wafer packaging structure provided by the embodiment can be used for packaging a plurality of different chips, thereby having a higher integration level and a higher integration degree.

In the embodiment, the substrate 101 is preferably a silicon wafer, which has better hardness and flatness, so that the failure proportion of packaged devices can be effectively reduced; the method for forming the grooves in the substrate 101 specifically includes: forming alignment marks on one surface of the substrate 101 by laser, and etching at the alignment marks to form the grooves 102.

The chips 103 are adhered in the grooves 102, and the material sealing layer 104 covers the substrate 101.

As an optional embodiment, the material sealing layer 104 is filled in the grooves 102 and between the chips 103, a part of the material sealing layer 104 also covers the surfaces of the chips 103, and the upper surface of the material sealing layer 104 is flush with the tops of the connecting components of the chips 103.

Since the chips 103 are adhered in the grooves 102, and the material sealing layer is filled in the grooves 102, the chips 103 are fixed on the substrate 101 more firmly, in order to effectively avoid a dropping condition of the chips 103.

As an optional embodiment, the wiring layer includes a metal layer 109 and a metal rewiring layer 110, the metal layer 109 is formed on the material sealing layer and is electrically connected with the connecting components of the chips 103, and the metal rewiring layer 110 is formed on the metal layer 109.

The material of the metal layer 109 is titanium or copper, the metal layer 109 is formed on the surface of the material sealing layer by a physical vapor deposition technology (PVD, Physical Vapor Deposition), the metal layer 109 is used as a seed layer, the metal rewiring layer 110 is formed on the metal layer 109, and the metal layer 109 and the metal rewiring layer 110 form the wiring layer to achieve the functional system interconnection and wiring of the chips 103.

Since a part of the material sealing layer 104 covers the surfaces of the chips 103, the upper surface of the material sealing layer 104 is flush with the tops of the connecting components of the chips 103, and the wiring layer is arranged on the material sealing layer, the wiring layer only contacts the connecting components of the chips 103 and does not contact the other parts of the chips, in order to effectively reduce the interference of the chips and improve the insulativity of the chips.

The protective film layer 105 is formed on the wiring layer, the openings 106 are formed in corresponding positions on the protective film layer 105, the lower ball metal layers 107 is formed in the openings, and metal balls 108 are formed on the lower ball metal layers 107.

As an optional embodiment, a bottom packaging layer is formed on the other surface of the substrate, namely the side of the substrate with no chip adhered, to protect the packaging structure on one hand and facilitate the heat dissipation of the packaging structure on the other hand, and in addition, such information as a product model number and the like can also be marked on the bottom packaging layer.

As an optional embodiment, the material for forming the material sealing layer 104 is epoxy resin, and the material is good in sealing property and can be easily plastic packaged, thus being a preferred material for forming the material sealing layer 104. As an optional embodiment, the connecting components are bonding pads of the chips.

To further illustrate the advantages of the wafer packaging structure provided by the present invention, a further description of the wafer packaging structure provided by the present invention will be given below in combination with a specific packaging method embodiment.

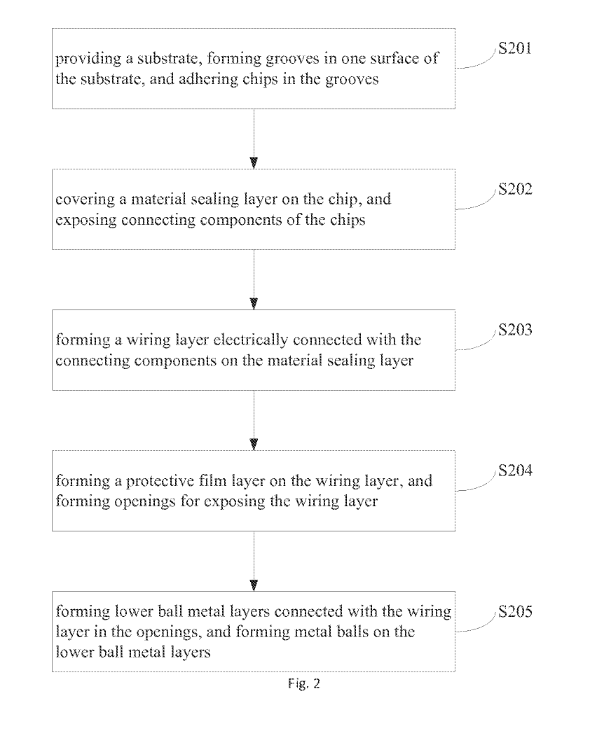

As shown in FIG. 2, it is a flowchart of a wafer packaging method of an embodiment in the present invention, including:

step S201, providing a substrate, forming grooves in one surface of the substrate, and adhering chips in the groove;

step S202, forming a material sealing layer on the substrate, and exposing connecting components of the chips;

step S203, forming a wiring layer electrically connected with the connecting components on the material sealing layer;

step S204, forming a protective film layer on the wiring layer, and forming openings for exposing the wiring layer; and

step S205, forming lower ball metal layers connected with the wiring layer in the openings, and forming metal balls on the lower ball metal layers.

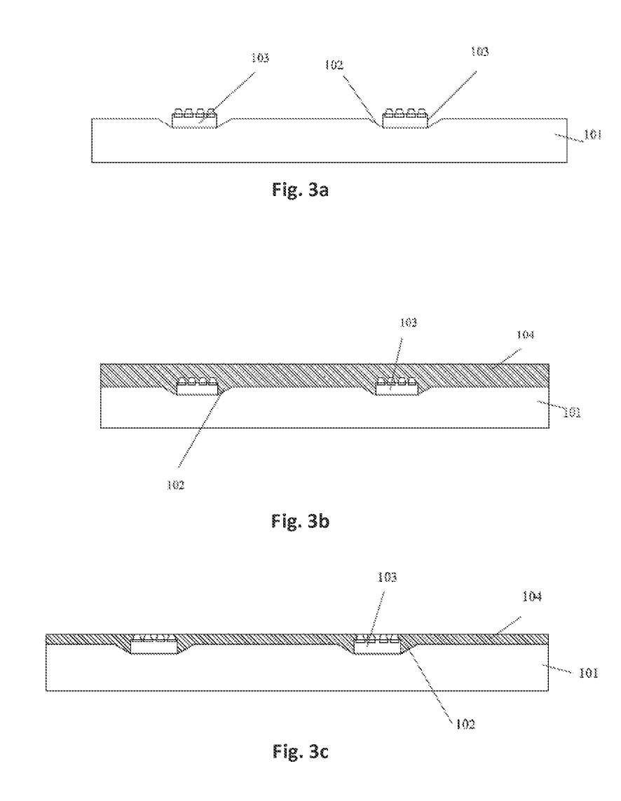

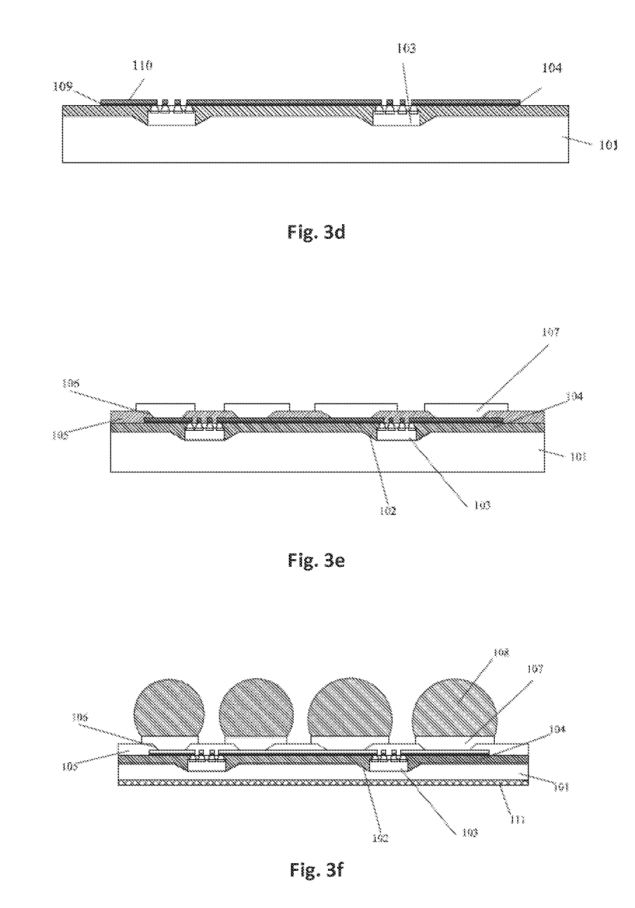

Step S201 is carried out at first, see FIG. 3a to FIG. 3f, including: providing the substrate 101, forming alignment marks on one surface of the substrate 101 by laser, and etching at the alignment marks to form the grooves 102, adhering the chips 103 in the grooves 102 and exposing functional surfaces of the chips 102.

The functional surfaces of the chips 102 are the surfaces where the connecting components are located.

The substrate 101 is preferably a silicon wafer.

Then, step S202 is carried out to form the material sealing layer 104 on the substrate 101. The specific method includes: filling the material sealing layer in the grooves 102 and between the chips 103, and covering the surfaces of the chips 103; then grinding the material sealing layer 104 to expose the connecting components on the chips 103, in order to enable the upper surface of the material sealing layer to be flush with the tops of the connecting components of the chips.

Since the chips 103 are adhered in the grooves 102, and the material sealing layer is filled in the grooves 102, the chips 103 are fixed on the substrate 101 more firmly, in order to effectively avoid a dropping condition of the chips 103.

In addition, the material sealing layer is ground to enable the upper surface of the material sealing layer 104 to be flush with the tops of the connecting components of the chips, and the connecting components of the chips are just exposed to ensure that the connecting components of the chips are coplanar, in order to improve the reliability of the packaging structure.

Step S203 is carried out to form the wiring layer electrically connected with the connecting components on the material sealing layer 104. The specific method includes: forming a metal layer 109 on the material sealing layer 104, and the process for forming the metal layer 109 adopts a physical vapor deposition (PVD) technology. The physical vapor deposition technology refers to achieving mass transfer in a physical process and transferring atoms or molecules from a source onto the surface of a base material. The physical vapor deposition technology can be used for spray coating some particles with special performance, for example high strength, wearing resistance, heat dissipation and corrosion resistance on a matrix with lower performance, to enable the matrix to have better performance. The basic methods of the physical vapor deposition technology include vacuum evaporation, sputtering and ion plating. The technology is used for improving the bonding strength of a coating material and the provided matrix material and is suitable for a variety of materials, the coating is varied, the process time is shortened, the productivity is improved, the operation temperature of the coating technology is quite low, the part size deformation is small, no pollution is generated to the process environment, a plurality of coating materials can be selected, and the material of the metal layer in the embodiment is preferably titanium or copper.

The metal layer 109 is used as a seed layer, the metal rewiring layer 110 is formed on the metal layer 109, and the metal layer 109 and the metal rewiring layer etched to achieve the functional system interconnection and wiring of the chips 103. Since a part of the material sealing layer 104 covers the surfaces of the chips 103, the upper surface of the material sealing layer 104 is flush with the tops of the connecting components of the chips 103, and the wiring layer is arranged on the material sealing layer, the wiring layer only contacts the connecting components of the chips 103 and does not contact the other parts of the chips, in order to effectively reduce the interference of the chips and improve the insulativity of the chips.

Step S204 and step S205 are carried out, including: forming the protective film layer 105 on the metal rewiring layer 110, forming the openings 106 for exposing the metal rewiring layer 110 on the protective film layer 105, and forming the lower ball metal layers 107 connected with the metal rewiring layer 105 in the openings 106.

In addition, after forming the lower ball metal layers 107, the method further includes: grinding the side of the substrate with no chip adhered, and forming a bottom packaging layer 111.

The substrate 101 is ground to decrease the thickness of the entire packaging structure, in order to meet the light, thin, short and small trend requirements of semiconductor packaging, and the grinding thickness is determined according to practical application demands.

The bottom packaging layer 111 can protect the packaging structure on one hand and can facilitate the heat dissipation of the packaging structure on the other hand. Laser marking is carried out on the bottom packaging layer 111 to mark such information as a product model and the like, for the convenience of subsequent application demands.

Finally, the metal balls 108 are formed on the lower ball metal layers 107.

The wafer packaging structure provided by the present invention can be used for packaging a plurality of different chips, thereby having a higher integration level and a higher integration degree; in addition, the wafer packaging structure satisfies the light, thin, short and small trend requirements of semiconductor packaging, and has high reliability.

Finally, it should be noted that: although the present invention and the advantages thereof have been described above in detail, it should be understood that a variety of variations, substitutions and modifications can be made without going beyond the spirit and the scope of the present invention limited by the appended claims. Moreover, the scope of the present invention is not limited to the specific embodiments of the processes, equipment, means, method and steps described in the description. According to the contents disclosed by the present invention, it is easy to be understood by those of ordinary skill in the art that existing and future processes, equipment, means, methods or steps to be developed can be used for implementing functions basically the same as the corresponding embodiments herein or obtaining basically identical results according to the present invention. Therefore, the appended claims are intended to include the processes, equipment, means, methods or steps within the scope thereof.

1. A wafer packaging structure, comprising:
a substrate, wherein grooves are formed in one surface of the substrate, and chips are arranged in the groove;
a material sealing layer formed on the substrate, wherein connecting components of the chips are exposed from the surface of the material sealing layer;
a wiring layer formed on the material sealing layer and electrically connected with the connecting components;
a protective film layer formed on the wiring layer, wherein the protective film layer is provided with openings for exposing the wiring layer;
lower ball metal layers formed in the openings and connected with the wiring layer; and
metal balls formed on the lower ball metal layers.

2. The wafer packaging structure of claim 1, wherein the material sealing layer is filled in the grooves and between the chips, a part of the material sealing layer also covers the surfaces of the chips, and the upper surface of the material sealing layer is flush with the tops of the connecting components of the chips.

3. The wafer packaging structure of claim 1, wherein the wiring layer comprises a metal layer and a metal rewiring layer, the metal layer is formed on the material sealing layer and is electrically connected with the connecting components of the chips, and the metal rewiring layer is formed on the metal layer.

4. The wafer packaging structure of claim 3, wherein the material of the metal layer is titanium or copper.

5. The wafer packaging structure of claim 1, wherein the substrate is a silicon wafer.

6. The wafer packaging structure of claim 1, wherein a bottom packaging layer is formed on the other surface of the substrate.

7. The wafer packaging structure of claim 1, wherein the material for forming the material sealing layer is epoxy resin.

8. The wafer packaging structure of claim 1, wherein each connecting component is a bonding pad of the chip.

9. A wafer packaging method, comprising:
providing a substrate, forming grooves in one surface of the substrate, and adhering chips in the groove;
forming a material sealing layer on the substrate, and exposing connecting components of the chips;
forming a wiring layer electrically connected with the connecting components on the material sealing layer;
forming a protective film layer on the wiring layer, and forming openings for exposing the wiring layer; and
forming lower ball metal layers connected with the wiring layer in the openings, and forming metal balls on the lower ball metal layers.

10. The wafer packaging method of claim 9, wherein the forming grooves in one surface of the substrate comprises: forming alignment marks on one surface of the substrate by laser, and etching the grooves on the alignment mark positions.

11. The wafer packaging method of claim 9, wherein the covering the chips with the material sealing layer and exposing connecting components of the chips comprises: filling the material sealing layer in the grooves and on the surfaces of the chips, and grinding the material sealing layer to enable the upper surface of the material sealing layer to be flush with the tops of the connecting components of the chips.

12. The wafer packaging method of claim 9, wherein the forming a wiring layer electrically connected with the connecting components on the material sealing layer comprises: sequentially forming a metal layer and a metal rewiring layer on the material sealing layer, and etching the metal layer and the metal rewiring layer to interconnect the chips.

13. The wafer packaging method of claim 12, wherein the material of the metal layer is titanium or copper.

14. The wafer packaging method of claim 9, wherein the substrate is a silicon wafer.

15. The wafer packaging method of claim 9, further comprising: grinding the side of the substrate with no chip adhered.

16. The wafer packaging method of claim 9, wherein a bottom packaging layer is formed on the side of the substrate with no chip adhered.

17. The wafer packaging method of claim 9, wherein the material for forming the material sealing layer is epoxy resin.

18. The wafer packaging method of claim 9, wherein each connecting component is a bonding pad of the chip.
